(19) United States
(12) Patent Application Publication
(10) Pub. No.: US 2026/0068722 A1
(43) Pub. Date: Mar. 5, 2026

(54) SEMICONDUCTOR MODULE AND METHOD OF MANUFACTURING SEMICONDUCTOR MODULE

(71) Applicants: SHINDENGEN ELECTRIC MANUFACTURING CO., LTD., Tokyo (JP); Mitsubishi Electric Corporation, Tokyo (JP)

(72) Inventors: Koichiro NOGUCHI, Tokyo (JP); Kosuke YAMAGUCHI, Tokyo (JP); Yasuhiro IMAZEKI, Saitama (JP)

(21) Appl. No.: 18/970,904

(22) Filed: Dec. 6, 2024

(30) Foreign Application Priority Data
Dec. 15, 2023 (JP) 2023-212299

(51) Int. Cl. H01L 23/13; H01L 23/367; H01L 23/498; H01L 25/00; H01L 25/07; H10D 80/20; H10D 80/30

(52) U.S. Cl. CPC H01L 23/13; H10D 80/215; H10D 80/231; H10D 80/30

(57) ABSTRACT

A semiconductor module includes: a board that includes a wiring portion formed on at least one surface and a hole portion having an opening on the at least one surface side; and a body portion that is disposed on one surface side of the board and is sealed by a resin, and a lead portion having a plate shape that extends toward an outside from a side surface of the body portion. In at least one semiconductor package, a part of the body portion is inserted into the hole portion, and the lead portion extends along a surface of the board, and a lower surface of the lead portion is bonded to the wiring portion.

### CROSS REFERENCE TO RELATED APPLICATIONS

This application claims priority to Japanese Patent Application No. 2023-212299, filed on Dec. 15, 2023, which is expressly incorporated herein by reference in its entirety.

### TECHNICAL FIELD

The present invention relates to a semiconductor module and a method of manufacturing a semiconductor module.

### BACKGROUND ART

Conventionally, a semiconductor module on which a plurality of semiconductor packages are mounted has been known (for example, see patent literature 1). As such a semiconductor package that uses semiconductor modules, there exists, an insertion-type semiconductor package having a lead portion that extends in a straight line shape from a side surface of a body portion toward the outside; and a face-mounting-type semiconductor package where a lead portion is bent in a z shape or the like in an intermediate portion thereof.

In mounting the insertion-type semiconductor packages (bonding the semiconductor packages to a board), for example, lead portions that extend in a straight line shape are immersed (soaked) into melted solder, and the lead portions are inserted into through holes formed in the board thus bonding the lead portions with the board. On the other hand, when the face-mounting-type semiconductor packages are mounted (bonded to the board), for example, lead portions are disposed on wiring portions (electrode pads) on the board by way of cream soldering or the like and by reflowing the lead portions thus bonding the lead portions with the board.

Recently, along with the number of cases where electronic parts are mounted on both surfaces of a board, a face-mounting-type semiconductor package where electronic parts can be mounted on both surfaces of a board becomes a mainstream. However, there exists a circumstance where insertion-type semiconductor packages are also still used, and the number of cases that the insertion-type semiconductor packages are used is still large.

In the semiconductor module that uses the insertion-type semiconductor packages, for example, a semiconductor module described hereinafter is known (a conventional first semiconductor module 900).

As illustrated in FIG. 8, the conventional first semiconductor module 900 includes: a board 910 having wiring portions 912 formed on one side surface thereof and through holes 914; two semiconductor packages 920, 930 having body portions 921, 931 that are sealed by a resin and lead portions 922, 932 extending from side surfaces of the body portions 921, 931 to the outside; and other semiconductor packages 940. Two semiconductor packages 920, 930 are insertion-type semiconductor packages, and other semiconductor packages 940 are face-mounting-type semiconductor packages.

### CITATION LIST

### Patent Literature

JP-A-6-310844

### SUMMARY OF INVENTION

### Technical Problem

However, in the above-mentioned prior art, the lead portions of the insertion-type semiconductor package are disposed perpendicular to the surface of the board and hence, there exists a drawback that downsizing and lowering of a height of the semiconductor module are difficult.

In the technical filed of the semiconductor module, there has been a demand for a semiconductor module that satisfies downsizing and lowering of a height. However, even in a case where lead portions of an insertion-type semiconductor package are extended along a surface of the board instead of a direction perpendicular to the surface of the board, the lead portions are mounted in a state where the lead portions are bent and are extended in a laterally extended manner (see FIG. 9) and hence, the height of lead portions cannot be lower than a thickness of the semiconductor package. Accordingly, there exists a drawback that the manufacture of a semiconductor module that satisfies downsizing and lowering of a height is difficult.

Further, in a case where heat radiation fin are used in common by two semiconductor packages, to adjust mounting heights from the board, it is necessary to insert a spacer between the semiconductor package and the board (see FIG. 9 to FIG. 12) or it is necessary to apply working to heat radiation fin (see heat radiation fin 950a illustrated in FIG. 10 to FIG. 12) and hence, it is further difficult to realize downsizing and lowering of a height of a semiconductor module.

In view of the above-mentioned circumstances, it is an object of the present invention to provide a semiconductor module that can realize downsizing and lowering of a height of the semiconductor module.

### Solution to Problem

A semiconductor module according to the present invention includes: a board that includes a wiring portion formed on at least one surface of the board, and a hole portion having an opening that is formed on the at least one surface side of the board; and at least one semiconductor package that includes a body portion disposed on the one surface side of the board and sealed by a resin, and a lead portion having a plate shape that extends toward an outside from a side surface of the body portion, wherein in at least one semiconductor package, a part of the body portion is inserted into the hole portion, the lead portion extends at a height position along a surface of the board, and a lower surface of the lead portion is bonded to the wiring portion.

### Advantageous Effects of the Present Invention

According to the semiconductor module of the present invention, the semiconductor module includes the board that includes the hole portion having the opening that is formed on at least one surface side of the board, and in at least one semiconductor package, a part of the body portion is inserted into the hole portion, the lead portion extends at the height position along the surface of the board, and the lower surface of the lead portion is bonded to the wiring portion. Accordingly, it is possible to make the lower surface of the lead portion and the wiring bonded with each other without bending the lead portion of the semiconductor package of an insertion type.

Further, according to the semiconductor module of the present invention, in at least one semiconductor package, a part of the body portion is inserted into the hole portion and hence, the body portion can be set lower than a thickness of the semiconductor package whereby it is possible to provide the semiconductor module that can realize downsizing and lowering of height.

### BRIEF DESCRIPTION OF DRAWINGS

FIG. 1 is a cross-sectional side view illustrating a semiconductor module 1 according to an embodiment 1.

FIG. 2A to FIG. 2C are views illustrating a rectifying semiconductor package 20 according to the embodiment 1. FIG. 2A is a cross-sectional side view of a rectifying semiconductor package 20, FIG. 2B is a plan view of the rectifying semiconductor package 20, FIG. 2C is a view illustrating the internal structure of the rectifying semiconductor package 20.

FIG. 3 is a cross-sectional side view illustrating a semiconductor module 2 according to an embodiment 2.

FIG. 4A and FIG. 4B are views illustrating a controlling semiconductor package 30a according to the embodiment 2. FIG. 4A is a cross-sectional side view of the controlling semiconductor package 30a, and FIG. 4B is a plan view of the controlling semiconductor package 30a.

FIG. 5 is a cross-sectional side view illustrating a semiconductor module 3 according to an embodiment 3.

FIG. 6 is a cross-sectional side view illustrating a semiconductor module 4 according to an embodiment 4.

FIG. 7A and FIG. 7B are views illustrating a controlling semiconductor package 30b according to the embodiment 4. FIG. 7A is a cross-sectional side view of the controlling semiconductor package 30b and FIG. 7B is a plan view of the controlling semiconductor package 30b.

FIG. 8 is a cross-sectional side view a conventional first semiconductor module 900.

FIG. 9 is a cross-sectional side view illustrating a conventional second semiconductor module 901.

FIG. 10 is a cross-sectional side view illustrating a conventional third semiconductor module 902.

FIG. 11 is a cross-sectional side view illustrating a conventional fourth semiconductor module 903.

FIG. 12 is a cross-sectional side view illustrating a conventional fifth semiconductor module 904.

FIG. 13 is a cross-sectional side view illustrating a method of manufacturing a semiconductor module according to an embodiment 5.

### DESCRIPTION OF EMBODIMENTS

A semiconductor module and a method of manufacturing a semiconductor module according to the present invention are described based on embodiments illustrated in the drawings. The embodiments described hereinafter are not intended to limit the invention called for in Claims. Further, it is not always the case that all of various constitutional elements described in the embodiments and the combinations thereof are indispensable as means to solve the problems of the present invention.

### Embodiment 1

### 1. Configuration of Semiconductor Module 1 According to Embodiment 1

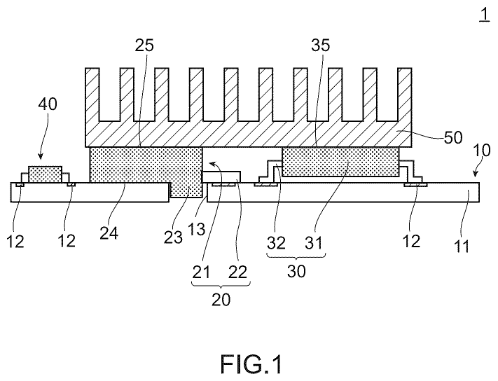

As illustrated in FIG. 1, the semiconductor module 1 according to the embodiment 1 includes: a board 10; two semiconductor packages (a rectifying semiconductor package 20 and a controlling semiconductor package 30); other semiconductor packages 40; and a heat radiation fin 50.

The board 10 includes an insulation board 11, wiring portions 12, and a hole portion 13. As the board 10, for example, a printed circuit board can be used. However, a ceramic board and other suitable wiring boards can be used.

The insulation board 11 is an insulation board formed using, for example, a glass epoxy resin as a material. However, the insulation board 11 may be an insulation board formed using a ceramic as a material, and the insulation board 11 may be other suitable insulation boards. The wiring portions 12 are constituted of circuits, lands, and electrode pads that are formed on one surface of the insulation board 11 using a copper foil or the like, for example. A solder resist is formed around the wiring portion 12. The hole portion 13 is a through hole having openings on both of one surface side and the other surface side of the insulation board 11. That is, the hole portion 13 has the opening that corresponds to a protruding portion 23 of the rectifying semiconductor package 20.

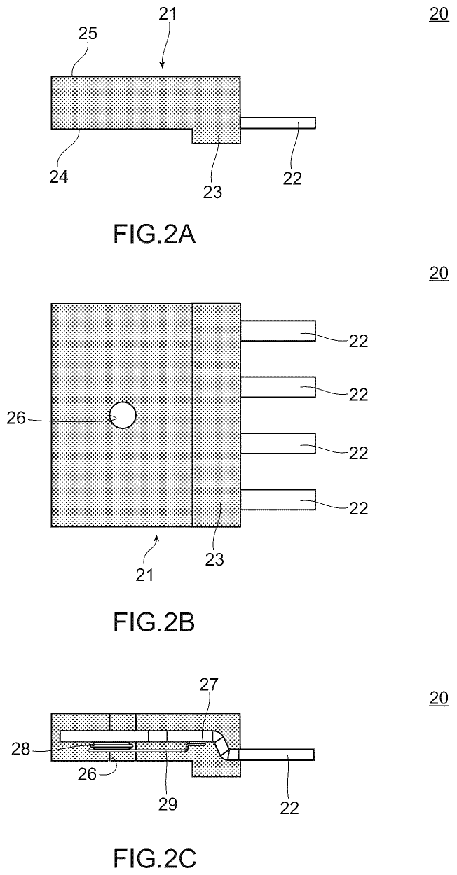

The rectifying semiconductor package 20 is disposed on one surface side of the board 10. As illustrated in FIG. 1 and FIG. 2A to FIG. 2C, the rectifying semiconductor package 20 is a so-called insertion-type semiconductor package having a body portion 21 and lead portions 22. The rectifying semiconductor package 20 is provided for applying, for example, full-wave rectification to an alternating current of a commercially available power source thus generating a pulsating current. For example, a bridge diode is constituted in the inside of the rectifying semiconductor package 20.

The body portion 21 has the protruding portion 23 that appears in an approximately L shape as viewed in a side view. The protruding portion 23 is formed in a protruding manner toward a board side using a heigh position of a board opposedly facing surface 24 on which the body portion 21 opposedly faces the board (see FIG. 1 and FIG. 2A). In such a configuration, in a case where the board opposedly facing surface 24 is brought into contact with the board 11 as illustrated in FIG. 1, the board opposedly facing surface may be also referred to as a board contact surface. Further, on a side of the body portion 21 opposite to a board side, a heat radiation fin mounting surface 25 on which heat radiation fin 50 are mounted is formed. That is, as illustrated in FIG. 1 and FIG. 2A, the body portion 21 has the board opposedly facing surface 24 and the heat radiation fin mounting surface 25 that are disposed on opposite sides from each other.

As illustrated in FIG. 1, the body portion 21 is disposed on one surface side of the board 10 in a state where the board contact surface 24 is brought into contact with the board 10 and, at the same time, in a state where the protruding portion 23 that forms a portion of the body portion 21 is inserted into the hole portion 13. Accordingly, no spacer is disposed between the body portion 21 and the board 10. A distal end of the protruding portion 23 may pass through the hole portion 13 and protrude from the opposite side of the board. Alternatively, the distal end of the protruding portion 23 may be retained in the hole portion 13.

The lead portions 22 are plate like members that extend toward the outside from a side surface of the body portion 21 (at an intermediate position of the side surface). In the embodiment 1, four lead portions 22 extend at a predetermined interval (see FIG. 2B). As illustrated in FIG. 1, the lead portions 22 extend horizontally at a height position along the surface of the board 10, and are not bent. Lower surfaces of the lead portions 22 are bonded to the wiring portion 12 via a conductive bonding material (for example, solder). Although the board contact surface 24 and the lower surfaces of the lead portions are at the same height position, even in a case where the board contact surface 24 and lower surfaces of the lead portions are at different height positions, the height positions of the board contact surface 24 and lower surfaces of the lead portions may be aligned with each other by adjusting a depth of the hole portion.

The lead portion 22 protrudes from the body portion 21 at a position separated from a height position of the heat radiation fin mounting surface 25 by a predetermined height or more. This is because it is necessary to set the height position by which an insulation distance between the lead portion 22 and the heat radiation fin 50 when the heat radiation fin 50 is disposed can be secured.

In the body portion 21 of the rectifying semiconductor package 20, as illustrated in FIG. 2C, inner leads 27, semiconductor chips 28, and connecting members 29 are disposed.

Each inner lead 27 has a land on which the semiconductor chip 28 is mounted, and is bent in a crank shape from the land, and is connected to the lead portion 22. The semiconductor chip 28 is disposed on a land of the inner lead 27. In this embodiment, four diodes are disposed thus forming a bridge diode. The connecting members 29 connect electrodes of the semiconductor chips 28 on a side opposite to the inner leads 27, and are connected with the inner leads 27.

The inner leads 27 disposed in the body portion 21 are bent in a crank shape from portions on which the semiconductor chips 28 are mounted, and extend to the outside of the sealed resin thus forming the lead portions 22 (outer leads). Accordingly, it is necessary to cover the inner leads 27, particularly the portions of the inner leads 27 bent in a crank shape with the sealed resin sufficient for insulating the inner leads 27 from the outside and hence, a protruding portion 23 that protrudes from the body portion 21 is formed on the body portion 21. Accordingly, the lead portions 22 protrude from the body portion 21 at an intermediate position on a side surface of the body portion 21 on a side where the protruding portion 23 is formed.

As illustrated in FIG. 1, the controlling semiconductor package 30 is a so-called surface mounting type semiconductor package that includes a body portion 31 and a lead portion 32. The controlling semiconductor package 30 controls driving of an electrically operated machine such as a motor disposed outside.

The body portion 31 is sealed by a resin in an approximately rectangular parallelepiped shape. The lead portion 32 extends toward the outside from a side surface of the body portion 31, and is bent in a crank shape or a gull wing shape at an intermediate portion of the side surface. A distal end portion of the lead portion 32 is disposed above a wiring portion 12, and is bonded to the wiring portion 12 via a conductive bonding material (for example, solder).

In the controlling semiconductor package 30, a heat radiation fin mounting surface 35 on which the heat radiation fin 50 is mounted is formed on a side opposite to a board side. A height position of the heat radiation fin mounting surface 25 of the rectifying semiconductor package 20 is substantially equal to a height position of the heat radiation fin mounting surface 35 of the controlling semiconductor package 30. To be more specific, the height from the height position of a board contact surface 24 of the rectifying semiconductor package 20 (a lower surface of the lead portion 22) to the height position of the heat radiation fin mounting surface 25 is equal to the height from the height position of the lowermost surface of the lead portion 32 of the controlling semiconductor package 30 to the height position of the heat radiation fin mounting surface 35.

Other semiconductor packages 40 are so-called surface mounting type semiconductor packages, and are disposed on the board 10. Although electronic parts such as capacitors are mounted on the board, basically these electronic parts are surface mounting type parts.

The heat radiation fin 50 is disposed in a straddling manner over the rectifying semiconductor package 20 and the controlling semiconductor package 30. The heat radiation fin 50 is a heat radiation fin used in a common by the rectifying semiconductor package 20 and the controlling semiconductor package 30.

### 2. Advantageous Effects Acquired by Semiconductor Module 1 According to Embodiment 1

The semiconductor module 1 according to the embodiment 1 includes the board 10 that includes the hole portion 13 having an opening that is formed on at least one surface side of the board 10. In at least any one of the semiconductor packages, a portion of the body portion 21 is inserted into the hole portion 13, the lead portion 22 extends horizontally at the height position along the surface of the board, and a lower surface of the lead portion 22 is bonded to the wiring portion 12. Accordingly, a lower surface of the lead portion 22 and the wiring portion 12 can be bonded to each other without bending the lead portion 22 of the insertion type semiconductor package 20.

Further, according to the semiconductor module 1 of the embodiment 1, in at least any one of the semiconductor packages 40, the portion of the body portion 21 is inserted into the hole portion 13. Accordingly, the height of the body portion 21 can be set lower than a thickness of the semiconductor package 20 and hence, it is possible to provide the semiconductor module that has realized downsizing and lowering of the height.

Further, according to the semiconductor module 1 of the embodiment 1, the body portion 21 has: a board opposedly facing surface 24 that is brought into contact with or opposedly faces the board 10; and the protruding portion 23 that protrudes toward the board 10 side using the height position of the board opposedly facing surface 24 as the reference, and the portion of the body portion 21 forms the protruding portion 23. Accordingly, the protruding portion 23 can be inserted into the hole portion 13, the lead portion 22 can be extended horizontally at the height position along the front surface of the board 10, and a lower surface of the lead portion 22 can be bonded to the wiring portion 12. Accordingly, the lower surface of the lead portion 22 and the wiring portion 12 can be bonded to each other without bending the lead portion 22 of the insertion-type semiconductor package. Further, although the semiconductor package is the insertion-type semiconductor package, in the same manner as the surface mounting type semiconductor package, the semiconductor package can be bonded to the board 10 by reflowing. Accordingly, it is unnecessary to perform the bonding in the surface mounting type semiconductor package and the bonding in the insertion-type semiconductor package separately and hence, the operation steps can be simplified.

Further, according to the semiconductor module 1 of the embodiment 1, even in a case where two or more semiconductor packages use the heat radiation fin 50 in common, the depth of the hole portion can be adjusted and hence, mounting heights of the semiconductor packages 20 from the board 10 can be aligned without inserting a spacer between the rectifying semiconductor package 20 and the board 10 or without applying machining to the heat radiation fin. Accordingly, it is possible to provide the semiconductor module which can realize downsizing and lowering of the height.

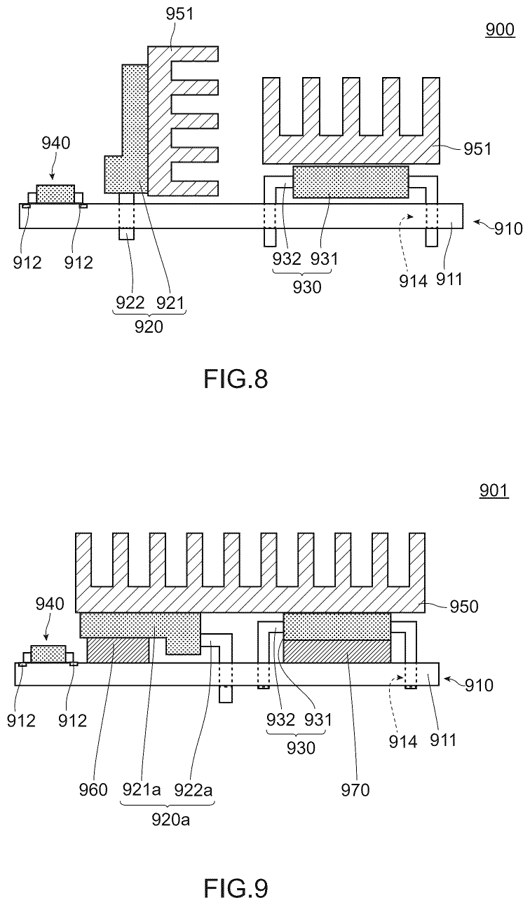

In the insertion-type semiconductor package, the lead portions extend from the side surface of the body portion. Accordingly, in a case where the semiconductor package is mounted in a state where the semiconductor package is erected, the mounting height becomes high (see a semiconductor package 920 in FIG. 8, the conventional first semiconductor module 900). Also in this case, a common heat radiation fin 50 cannot be placed on two semiconductor packages. In view of the above, the configuration is adopted where the lead portions are bent in an L shape and hence, the lead portions are disposed in a horizontally elongated manner whereby a mounting height is lowered (see a semiconductor package 930 illustrated: in FIG. 9, see a conventional second semiconductor module 901).

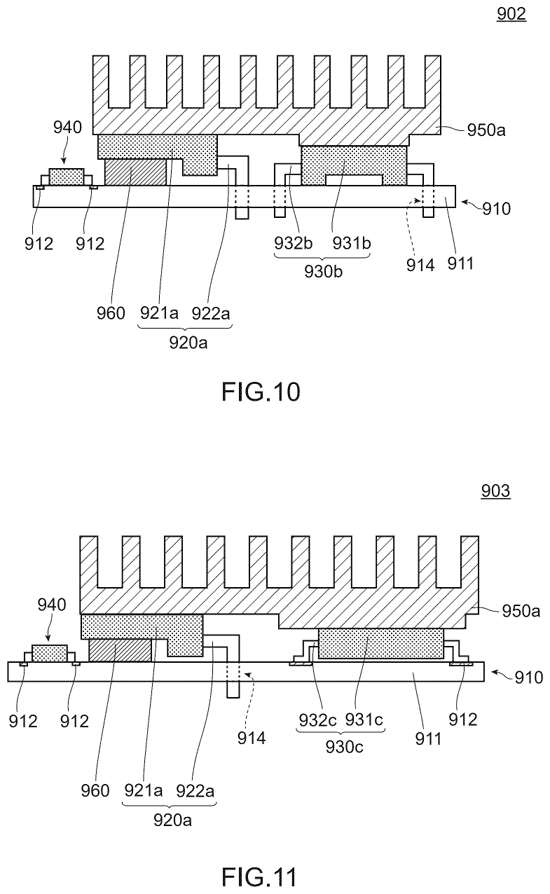

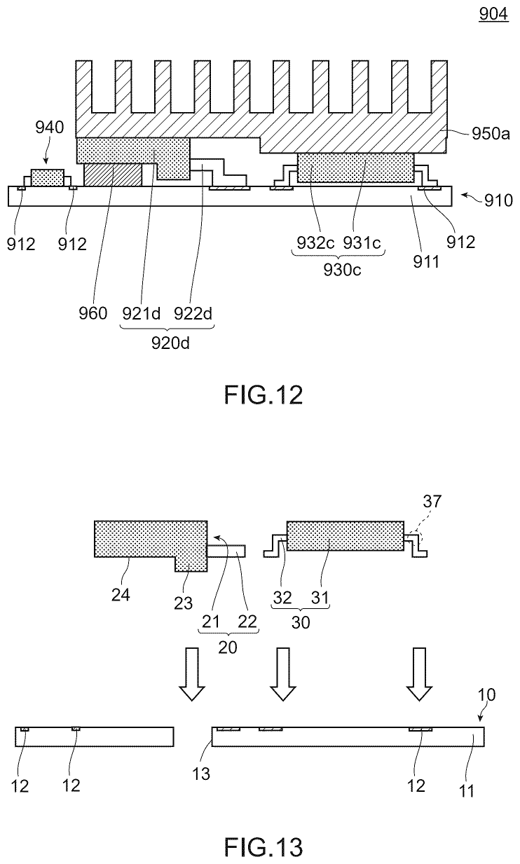

However, the rectifying semiconductor 920 and the controlling semiconductor package 930 largely differ from each other in both the role and the constitutional elements and hence, these semiconductors 920, 930 also differ from each other in thickness and mounting height. Accordingly, to mount the heat radiation fin 950 shared in common by them, the configuration is considered where spacers 960, 970 are inserted between the semiconductor packages 920, 930 and the board 910 so as to adjust their mounting heights thus enabling mounting of the common heat radiation fin (see FIG. 9, the conventional second semiconductor module 901), the configuration where the heat radiation fin are machined so that the difference in mounting height is compensated by protruding portions of the heat radiation fin by machining the heat radiation fin (see the heat radiation fin 950a in FIG. 10, see the conventional third semiconductor module 902).

This means that, even in a case where, out of two semiconductor packages, one semiconductor package (the controlling semiconductor package 930 in FIG. 11) is formed of a surface mounting type semiconductor package, and the other semiconductor package (the rectifying semiconductor package 920 in FIG. 11) is formed of an insertion type semiconductor package, it is necessary to perform the adjustment such as the insertion of a spacer or machining the heat radiation fin and hence, the common heat radiation fin cannot be easily mounted (see FIG. 11, see the conventional fourth semiconductor module 903).

On the other hand, in an attempt to form a surface mounting type semiconductor package by bending lead portions of an insertion type semiconductor package, a thickness of the lead portion originally formed for the insertion type semiconductor package is large and hence, it is difficult to bend the lead portion, and a mounting surface is increased whereby there arises a drawback that it is difficult to realize downsizing of the semiconductor module.

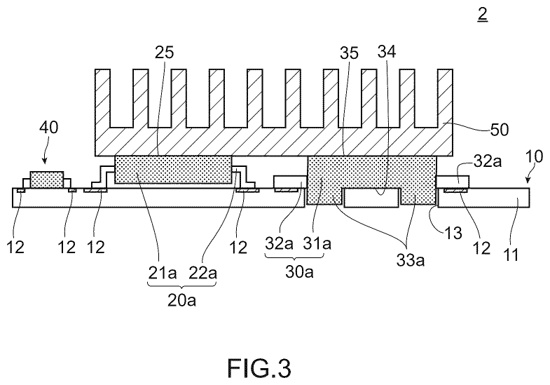

To the contrary, in the semiconductor module 1 according to the embodiment 1, by setting heat radiation fin mounting surfaces of two semiconductor packages at the same height, the common heat radiation fin can be mounted on two semiconductor packages simply without inserting the spacers or without machining the heat radiation fin. To be more specific, as illustrated in FIG. 1 and FIG. 3, the heat radiation fin mounting surfaces 25 of the controlling semiconductor package 20, 20a and the heat radiation fin mounting surfaces 35 of the rectifying semiconductor packages 30, 30a are at same height with each other using the height position of the upper surface of the insulation board 11 as the reference. Accordingly, the common heat radiation fin 50 can be simply mounted.

Further, in the semiconductor module according to the embodiment 1, out of the plurality of semiconductor packages, one semiconductor package is the controlling semiconductor package 20, and the other semiconductor package out of the plurality of semiconductor packages is the rectifying semiconductor package 30. Accordingly, downsizing and lowering of height of the semiconductor package that forms a core portion of the semiconductor module can be realized and, at the same time, downsizing and lowering of height of the semiconductor module can be realized.

### Embodiment 2

The semiconductor module 2 according to the embodiment 2 has basically substantially the same configuration as the semiconductor module 1 according to the embodiment 1. However, the semiconductor module 2 according to the embodiment 2 differs from the semiconductor module 1 according to the embodiment 1 with respect to a point that, in the semiconductor module 2 according to the embodiment 2, a rectifying semiconductor package is a surface mounting type semiconductor module, and the controlling semiconductor package is an insertion type semiconductor package.

In the embodiment 2, as illustrated in FIG. 3, a rectifying semiconductor package 20a has a body portion 21a and lead portions 22a. The body portion 21a is sealed by a resin in an approximately rectangular parallelepiped shape. The lead portions 22a extend toward the outside from a side surface of the body portion 21a, are bent in a crank shape or gull wing shape at intermediate portions thereof. Distal end portions of the lead portion 22a are disposed on a wiring portion 12, and bonded to conductive bonding materials (for example, solders).

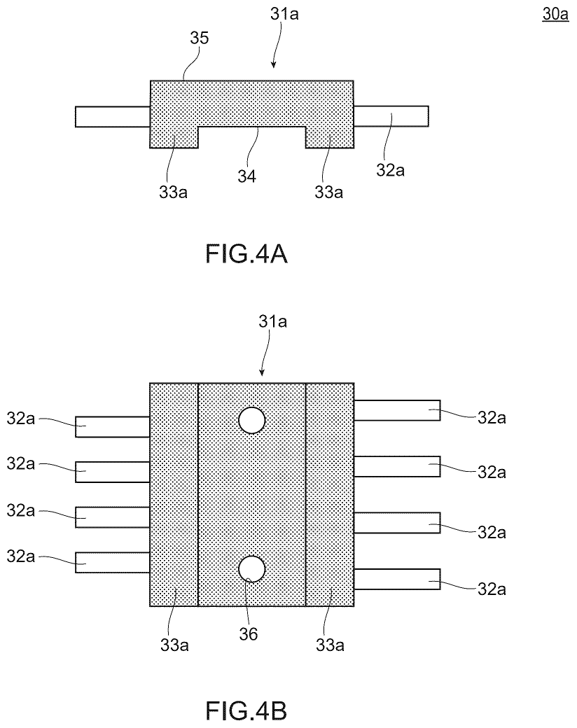

As illustrated in FIG. 3 and FIG. 4A and FIG. 4B, the controlling semiconductor package 30a has a body portion 31a and a lead portions 32a.

The body portion 31a is sealed by a resin, and has a U shape that opens downward as viewed in a side view. A board contact surface 34 that opposedly faces and is brought into contact with the board 10 is formed in the vicinity of a lower center of the body portion 31a. The body portion 31a has, at both ends thereof two protruding portions 33a, 33a that protrude toward a board 10 side using a height position of the board contact surface 34 as the reference. The protruding portions 33a are inserted into hole portions 13 formed in the board 10. On a side opposite to a board side, a heat radiation fin mounting surface 35 that mounts a heat radiation fin 50 thereon is formed.

The body portion 31a has an approximately rectangular shape as viewed in a plane view, and the protruding portions 33a are formed along two opposedly facing sides of the body portion 31a. For example, four lead portions 32a extend from side portions of the body portion 31a on sides where the protruding portions 33a are formed respectively. For example, two through holes 36 by which the heat radiation fin 50 is fixed are formed along a line that passes the center of the body portion 31a.

The lead portions 32a are plate-shaped members that extend toward the outside from the side surface on one side of the body portion 31a on which the protruding portion 33a is formed. In the embodiment 1, four lead portions 32a extend from each of two sides of the body portion 31a disposed on opposite sides. As illustrated in FIG. 3, the lead portions 32a are at the height position of the surface of the board 10 when the protruding portions 33a are inserted into the hole portion 13 and hence, the lead portions 32a extend horizontally at the height position along a front surface of the board 10. Lower surfaces of the lead portions 32a are bonded to the wiring portions 12 via a conductive bonding material (for example, solder).

In this manner, the semiconductor module 2 according to the embodiment 2 differs from the case of the semiconductor module 1 according to the embodiment 1 with respect to the point that the rectifying semiconductor package is a surface mounting type and the controlling semiconductor package is an insertion type. However, in the same manner as the semiconductor module 1 according to the embodiment 1, the semiconductor module 2 according to the embodiment 2 includes the board 10 that includes the hole portion 13 having the opening that is formed on the at least one surface side of the board 10, and in at least either one of the semiconductor packages, a portion of the body portion 31a is inserted into the hole portion 13, the lead portions 32a extend horizontally at the height position along the surface of the board 10, and lower surfaces of the lead portions 32a are bonded to the wiring portion 12. Accordingly, the lower surfaces of the lead portions 32a and the wiring portion 12 can be bonded to each other without bending the lead portions 32a of the insertion type semiconductor package 30a.

Further, according to the semiconductor module 2 of the embodiment 2, in at least either one of the semiconductor packages, the portion of the body portion 31a is inserted into the hole portion 13. Accordingly, a thickness of the body portion 31a can be set smaller than a thickness of the semiconductor package 30a thus providing the semiconductor module that can realize downsizing and lowering of the height.

The semiconductor module 2 according to the embodiment 2 has substantially the same configuration as the semiconductor module 1 according to the embodiment 1 with respect to the points other than the point that the rectifying semiconductor package is of a surface mounting type and the controlling semiconductor package is of an insertion type and hence, the semiconductor module 2 according to the embodiment 2 can acquire advantageous effects corresponding to the advantageous effects of the semiconductor module 1 according to the embodiment 1 amongst all the advantageous effects that the embodiment 1 acquires.

### Embodiment 3

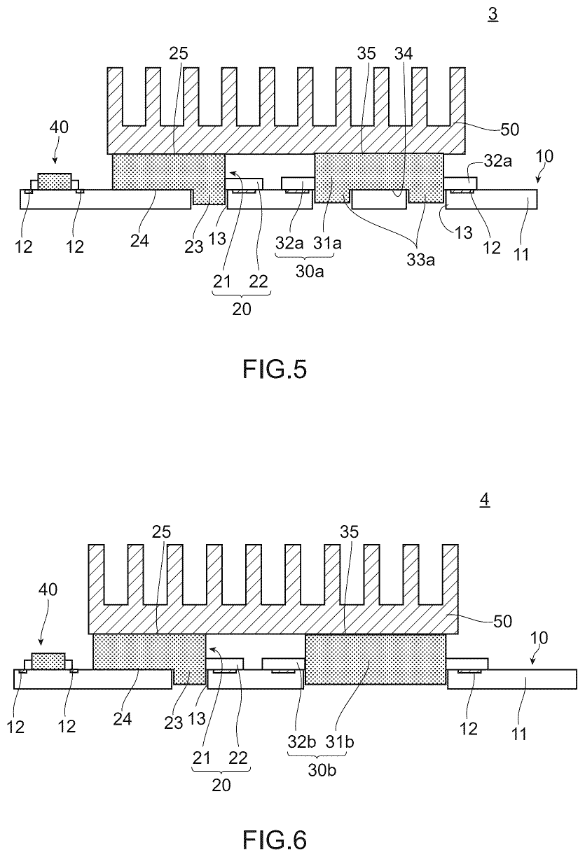

A semiconductor module 3 according to the embodiment 3 has basically substantially the same configuration as the semiconductor module 1 according to the embodiment 1. However, the semiconductor module 3 according to the embodiment 3 differs from the semiconductor module 1 according to the embodiment 1 with respect to a point that both a rectifying semiconductor package and a controlling semiconductor package are formed of an insertion type semiconductor package. That is, in the embodiment 3, as illustrated in FIG. 5, the rectifying semiconductor package is the insertion type rectifying semiconductor package 20 used in the embodiment 1, and the controlling semiconductor package is the insertion type controlling semiconductor package 30a used in the embodiment 2.

In this manner, the semiconductor module 3 according to the embodiment 3 differs from the semiconductor module 1 according to the embodiment 1 with respect to the point that both the rectifying semiconductor package and the controlling semiconductor package are formed of an insertion type semiconductor package. However, in the same manner as the semiconductor module 1 according to the embodiment 1, the semiconductor module 3 according to the embodiment 3 includes a board 10 in which a hole portion 13 having an opening on at least one surface side of the board 10 is formed, a portion of the body portion 21, 31a in either one of semiconductor package, a portion of the body portion 21, 31a is inserted into the hole portion 13, the lead portions 22, 32a extend horizontally at the height position along a front surface of the board 10, and lower surfaces of the lead portions 22, 32a are bonded to wiring portions 12. Accordingly, the lower surfaces of the lead portions 22, 32a and the wiring portion 12 can be bonded to each other without bending the lead portions 22, 32a of the insertion type semiconductor packages 20, 30a.

Further, according to the semiconductor module 3 of the embodiment 3, in any one of the semiconductor packages, a portion of the body portion 21, 31a is inserted into the hole portion 13 and hence, a height of the body portion 21, 31a can be set lower than a thickness of the semiconductor package 20, 30a. Accordingly, it is possible to form the semiconductor module 3 into a semiconductor module that has realized downsizing and lowering of height.

The semiconductor module 3 according to the embodiment 3 has substantially the same configuration as the semiconductor module 1 according to the embodiment 1 with respect to the points other than the point that both the rectifying semiconductor package and the controlling semiconductor package are of an insertion type and hence, the semiconductor module 3 according to the embodiment 3 can acquire advantageous effects corresponding to the advantageous effects of the semiconductor module 1 according to the embodiment 1 amongst all the advantageous effects that the embodiment 1 acquires.

### Embodiment 4

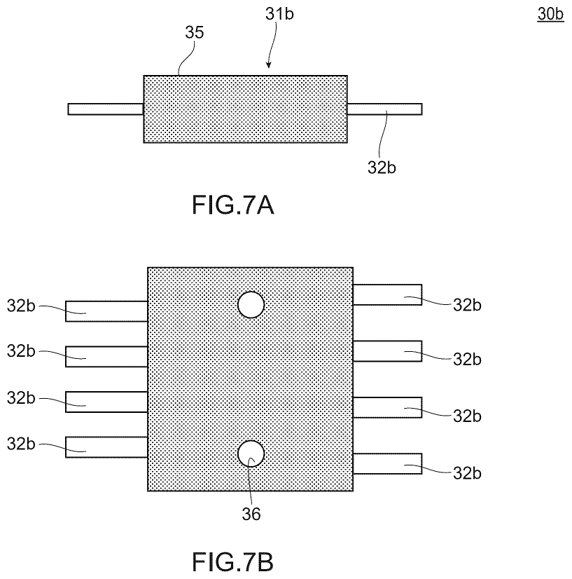

As illustrated in FIG. 6 and FIG. 7A and FIG. 7B, a semiconductor module 4 according to the embodiment 4 has basically substantially the same configuration as the semiconductor module 1 according to the embodiment 1. However, the semiconductor module 4 according to the embodiment 4 differs from the semiconductor module 1 according to the embodiment 1 with respect to the configuration of a portion of a body portion 31b of a controlling semiconductor package in an external appearance. That is, in the embodiment 4, in a controlling semiconductor package 30b, the shape of the body portion 31b is not limited to the shape where a portion of the body portion 31a is formed into a protruding portion. In FIG. 6, the body portion 31b is formed in a rectangular parallelepiped shape by resin sealing, and a portion of the body portion 31b is inserted into the hole portion 13.

A portion of a body portion 31b of the controlling semiconductor package 30b positioned below a lower surface of the lead portion 32b is inserted into a hole portion 13 formed in the board 10. In other words, the lower surface of the lead portion 32b of the controlling semiconductor package 30b is positioned at the same height of a board opposedly facing surface (board contact surface) of the controlling semiconductor package 30b, and the entirety of the body portion 31b on a side lower than the height position is inserted into the hole portion 13. Accordingly, it may be also expressed that a portion of the body portion 31b lower than the height position of the lower surface of the lead portion 32b corresponds to the portion of the body portion 31b.

In this manner, the semiconductor module 4 according to the embodiment 4 shares the common configuration as the semiconductor module 1 according to the embodiment 1 with respect to the part of the body portion on a controlling semiconductor package. However, the semiconductor module 4 according to the embodiment 4 differs from the semiconductor module 1 according to the embodiment 1 with respect to the point that the shape of the part is not a protruding portion. However, the semiconductor module 4 according to the embodiment 4 has the configuration where the semiconductor module 4 includes the board 10 having the hole portion 13 where an opening is formed in at least one surface side, the part of the body portion 31b is inserted into the hole portion 13, the lead portions 32b extend horizontally at the height position along the surface of the board 10, and the lower surfaces of the lead portions 32b are bonded to the wiring portions 12. Accordingly, the semiconductor module 4 includes the board 10 that has the hole portion 13 formed in at least one side surface of the board 10, and in at least one semiconductor package, the part of the body portion 21, 31b is inserted into the hole portion 13, the lead portions 22, 32b extend horizontally at the height position along the surface of the board 10, and the lower surfaces of the lead portions 22, 32b are bonded to the wiring portions 12 and hence, the lower surfaces of the lead portions 22, 32b and the wiring portions 12 can be bonded to each other without bending the lead portions 22, 23b of the insertion type semiconductor packages 20, 30b.

Further, according to the semiconductor module 4 according to the embodiment 4, in at least any one of semiconductor packages, the parts of the body portions 21, 31b are inserted into the hole portions 13 and hence, a height of the body portion 21, 31a can be set lower than a thickness of the semiconductor package 20, 30a. Accordingly, it is possible to form the semiconductor module 4 into a semiconductor module that has realized downsizing and lowering of height.

Further, according to the semiconductor module 4 of the embodiment 4, the portion lower than the height position of the lower surface of the lead portion 32b corresponds to the part of the body portion 31b. Accordingly, the structure where the lower surfaces of the lead portions 32b can secure a wider connection area thus further lowering a connection resistance than the structure where the lead portions 32b are inserted into the holes formed in a board 11. Further, the former structure can increase a connection strength and hence, the former structure can prevent the occurrence of a connection failure against vibrations, for example.

Further, according to the semiconductor module 4 of the embodiment 4, in at least any one of the semiconductor package, a part of the body portion (a part disposed below the lower surface of the lead portion) is inserted into the hole portion 13 and hence, the height of the lead portion can be set lower than a thickness of the semiconductor package whereby it is possible to provide the semiconductor module that has realized downsizing and lowering of height.

The semiconductor module 4 according to the embodiment 4 has substantially the same configuration as the semiconductor module 1 according to the embodiment 1 with respect to the configurations other than the configuration of the part of the body portion of the controlling semiconductor package and hence, the semiconductor module 4 according to the embodiment 4 can acquire advantageous effects corresponding to the advantageous effects of the semiconductor module 1 according to the embodiment 1 amongst all the advantageous effects that the embodiment 1 acquires.

### Embodiment 5

Next, a method of manufacturing a semiconductor module according to an embodiment 5 is described with reference to FIG. 13. First, the board 11 that includes the hole portion 13 having the opening on at least one surface side and the wiring portions 12; the first semiconductor package 20 that includes the first lead portions 22 having a plate shape that extend toward the outside from the side surface of the first body portion 21; and the second semiconductor package 30 that includes the second lead portions 32 having a plate shape that extend toward the outside from the side surface of the second body portion 31 and are bent so as to approach the board 11 are provided. At this step of the manufacturing method, the first body portion 21 and the second body portion 31 may be sealed by a resin. Further, in FIG. 13, the first semiconductor package 20 is of an insertion type, and the second semiconductor package 30 is of a surface mounting type.

Next, the protruding portion 23 that forms a portion of the first body portion 21 is inserted into the hole portion 13, and the lower surfaces of the first lead portions 22 are bonded to the wiring portions 12 on the board 10. In the same manner, the lower surfaces of the portions (distal end portions) of the second lead portions 32 that extend along the direction parallel to the surface of the board 11 are bonded to the wiring portions 12 of the board 11. With such operations, the first semiconductor package 20 is connected to the board 10 and, at the same time, the second semiconductor package 30 is connected to the board 10.

The present embodiment 5 is characterized in that the lower surfaces of the first lead portions 22 are bonded to the wiring portions 12 of the board 11 and, at the same time, the lower surfaces of the second lead portions 22 are bonded to the wiring portions 12 of the board 11. As a specific manufacturing method, for example, the lower surfaces of the first lead portions 22 and the lower surfaces of the second lead portions 32 may be bonded to the board 11 by single reflow processing.

With such a manufacturing method, although the first semiconductor package 20 is of an insertion type, the first semiconductor package 20 can be bonded to the board by processing such as reflow in the same manner as the second semiconductor package 30 of a surface mounting type and hence, the operation steps can be simplified.

In this embodiment 5, the first semiconductor package 20 and the second semiconductor package 30 are bonded to the board. However, the case where only the first semiconductor package 20 of an insertion type is bonded to the board can also acquire the above-mentioned advantageous effect. That is, the method of manufacturing a semiconductor module may include: a preparation step of preparing a board that has a hole portion having an opening on at least one surface side; and a connection step of connecting a body portion sealed by a resin and at least one first semiconductor package 20 that includes a lead portion having a plate shape extending toward an outside from a side surface of the body portion, wherein in the connection step, in at least any one first semiconductor package, a part of the body portion may be inserted into the hole portion, a lead portion may be disposed in a horizontally extending manner along a surface of the board, and a lower surface of the lead portion may be bonded to the board, thus connecting the first semiconductor package to the board. Also in this case, it is possible to acquire an advantageous effect, although the first semiconductor package 20 is of an insertion type, the first semiconductor package 20 can be bonded to the board by processing such as reflow in the same manner as the semiconductor package of a surface mounting type.

Further, in the same manner as the embodiment 1, in a case where one of two semiconductor packages is a controlling semiconductor package and the other is a rectifying semiconductor package, downsizing and lowering of a height of the semiconductor package that forms a core part of the semiconductor module can be realized and hence, downsizing and lowering of a height of the entire semiconductor module can be realized.

The present invention has been described based on the above-mentioned embodiments heretofore, the present invention is not limited to the above-mentioned embodiment. The present invention can be carried out in various modes without departing from the gist of the present invention. For example, the following modifications are also conceivable.

(1) The positions, the connections, the numbers and the like of constitutional elements described in the above-mentioned respective embodiments (also including respective modifications, the same definition being adopted hereinafter) also can be changed within a scope that advantageous effects of the present invention are not impaired.

(2) In the above-mentioned embodiment 4, as a part of the body portion of the controlling semiconductor package, the part that is not a protruding portion is inserted into the hole portion. However, the present invention is not limited such a configuration. A part of the body portion of the rectifying semiconductor package may be a part that is not a protruding portion may be inserted into the hole portion, or a part which is not a protruding portion may be inserted into the hole portion as parts of body portions of both the controlling semiconductor package and the rectifying semiconductor package.

(3) In the above-mentioned respective embodiments, the board where the wiring portion is formed only one surface of the board is used. However, the present invention is not limited to such a configuration. The present invention may also use a board where the wiring portion is formed on both one surface and the other surface of the board.

(4) In the above-mentioned respective embodiments, the hole portion 13 is a penetrating hole. However, the present invention is not limited to such a configuration. The hole portion 13 may be a hole that does not penetrate (a hole having an opening on one surface side).

(5) In the above-mentioned respective embodiments, the board opposedly facing surface is the board contact surface that is in contact with the board. However, the present invention is not limited to such a configuration. The board opposedly facing surface may not be in contact with the board.

(6) In the above-mentioned respective embodiments, the semiconductor module includes, as the semiconductor packages, three types of semiconductor packages. That is, the semiconductor module includes the controlling semiconductor package, the rectifying semiconductor package and the semiconductor packages for other purposes. However, the present invention is not limited to such a configuration. The semiconductor module may not include other semiconductor packages, or the semiconductor module may include only either one of the controlling semiconductor package or the rectifying semiconductor package. In other words, the semiconductor module may include one semiconductor package or may include a plurality of semiconductor packages. It is preferred that one semiconductor package out of the plurality of semiconductor packages is the controlling semiconductor package, and the other semiconductor package out of the plurality of the semiconductor packages is the rectifying semiconductor package.

1. A semiconductor module comprising:
a board that includes a wiring portion formed on at least one surface of the board, and a hole portion having an opening that is formed on the at least one surface side of the board; and
at least one semiconductor package that includes a body portion disposed on the one surface side of the board and sealed by a resin, and a lead portion having a plate shape that extends toward an outside from a side surface of the body portion, wherein
in at least one semiconductor package,
a part of the body portion is inserted into the hole portion,
the lead portion extends along a surface of the board, and
a lower surface of the lead portion is bonded to the wiring portion.

2. The semiconductor module according to claim 1, wherein
the semiconductor package includes a board opposedly facing surface that is in contact with or opposedly faces the board, and a protruding portion that protrudes toward the board side using a height position of the board opposedly facing surface as a reference, and
the part of the body portion is the protruding portion.

3. The semiconductor module according to claim 1 wherein
the semiconductor module includes a plurality of the semiconductor packages as the semiconductor package, a heat radiation fin mounting surface on which a heat radiation fin is mounted is formed on a least the two semiconductor packages out of the plurality of semiconductor packages respectively on a side of the body portion opposite to the board side, and the respective heat radiation fin mounting surfaces have a same height.

4. The semiconductor module according to claim 1, wherein
the semiconductor module includes a plurality of the semiconductor packages as the semiconductor package,
one semiconductor package out of the plurality of semiconductor packages is a controlling semiconductor package, and an other semiconductor package out of the plurality of semiconductor packages is a rectifying semiconductor package.

5. A method of manufacturing a semiconductor module comprising:
a preparation step of preparing a board that includes a hole portion having an opening on at least one surface side of the board; and
connection step of connecting at least one semiconductor package that includes a body portion sealed by a resin and a lead portion having a plate shape that extends toward an outside from a side surface of the body portion to the board, wherein,
in the connection step, with respect to the at least one semiconductor package, a part of the body portion is inserted into the hole portion, the lead portion is disposed so as to extend horizontally along a surface of the board, a lower surface of the lead portion is bonded to the board thus connecting the semiconductor package to the board.

6. A method of manufacturing a semiconductor module comprising:
a step of preparing a board that includes a hole portion having an opening on at least one surface side of the board;
a first step of connecting at least one first semiconductor package that includes a first body portion sealed by a resin and a first lead portion having a plate shape that extends toward an outside from a side surface of the first body portion to the board, and
a second step of connecting at least one second semiconductor package that includes a second body portion sealed by a resin and a second lead portion having a plate shape that extends toward an outside from a side surface of the second body portion, and a second lead portion having a plate shape that includes a bent portion so as to approach the second lead portion to the board, wherein
in the first step, with respect to the at least one first semiconductor package, a part of the first body portion is inserted into the hole portion, the first lead portion is disposed so as to extend along the surface of the board, and a lower surface of the first lead portion is bonded to the board thus connecting the first semiconductor package to the board, and
in the second step,
a lower surface of the second lead portion is bonded to the board thus connecting the second semiconductor package to the board, and
the bonding for bonding the lower surface of the first lead portion and the board to each other in the first step and bonding for bonding the lower surface of the second lead portion to the board in the second step are simultaneously performed.
